(19) United States
(12) Patent Application Publication
(10) Pub. No.: US 2007/0190674 A1
(43) Pub. Date: Aug. 16, 2007

(54) APPARATUS AND METHOD FOR MANUFACTURING DISPLAY DEVICE

(75) Inventors: Joo-hyeon LEE, Yongin-si (KR); Hoon KIM, Hwaseong-si (KR); Sang-pil LEE, Seoul (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/675,772

(22) Filed: Feb. 16, 2007

(30) Foreign Application Priority Data
Feb. 16, 2006 (KR) 1020060015277

(51) Int. Cl. H01L 21/00

(52) U.S. Cl. 438/21

(57) ABSTRACT

An apparatus for manufacturing a display device includes a stage on which a lower substrate is mounted, the stage including a plurality of lift pins formed on an entire surface of the stage, a gripper that grips at least three point parts of an upper substrate to be positioned above the lower substrate and an elevating part that vertically moves at least one of the stage and the gripper relative to each other.

This application claims priority to Korean Patent Application No. 2006-0015277, filed on Feb. 16, 2006, and all the benefits accruing therefrom under 35 U.S.C. §119, the contents of which are incorporated herein by reference in its entirety.

### BACKGROUND OF INVENTION

1. Field of Invention

The present invention relates to an apparatus and method for manufacturing a display device, and more particularly, an apparatus and method for manufacturing a display device including organic light emitting elements.

2. Description of the Related Art

As a kind of flat panel display, an OLED (organic light emitting diode) has become popular with advantages of low voltage driving, light weight, slimness, wide viewing angle, high response speed, etc. The OLED includes an OLED substrate provided with thin film transistors on which a light emitting material is formed. The OLED controls light emitted from the light emitting material to display images.

The light emitting material is formed of an organic material. Accordingly, the light emitting material is apt to be damaged by oxygen and water, thereby deteriorating durability thereof.

To protect the light emitting material, the OLED includes various protective members. The protective members may include a passivation layer made of an inorganic material, or a cap made of metal or glass.

A method of bonding a substrate on which a light emitting material is formed to another substrate has been developed.

### BRIEF SUMMARY OF THE INVENTION

An exemplary embodiment provides an apparatus and method for manufacturing a display device with improved durability, which is capable of preventing display elements from being deteriorated.

An exemplary embodiment provides an apparatus for manufacturing a display device. The apparatus includes a stage on which a lower substrate is mounted, the stage including a plurality of lift pins formed on an entire surface of the stage, a gripper that grips at least three point parts of an upper substrate to be positioned above the lower substrate and an elevating part that vertically moves at least one of the stage and the gripper relative to each other.

In an exemplary embodiment, the upper substrate includes a rectangular shape and the gripper grips four corners of the upper substrate.

In an exemplary embodiment the apparatus further includes a lift pin controller that controls the lift pins to gradually ascend from a predetermined part of the stage to a circumference of the stage.

In an exemplary embodiment, the apparatus further includes a light source part that emits light to the lower substrate and the upper substrate.

In an exemplary embodiment, the apparatus further includes a heater that heats the lower substrate and the upper substrate.

An exemplary embodiment provides a method for manufacturing a display device. The method includes providing a first substrate on which a display element is formed, providing a second substrate on the first substrate, the second substrate facing the first substrate, protruding a part of at least one of the first substrate and the second substrate toward the other, point-contacting the first substrate to the second substrate and gradually contacting the point-contacted first and second substrates toward circumferences of the first and second substrates.

In an exemplary embodiment, the second substrate includes a rectangular shape. The protruding a part of at least one of the first substrate and the second substrate includes gripping four corners of the second substrate so that one spot of the second substrate protrudes downward.

In an exemplary embodiment, the contacting the point-contacted first and second substrates includes lowering gradually the second substrate from the one spot to the circumference of the second substrate.

In an exemplary embodiment, the protruding a part of at least one of the first substrate and the second substrate includes mounting the first substrate on a stage including a plurality of lift pins vertically movably formed on an entire surface of the stage and moving upward a lift pin corresponding to one spot of the first substrate.

In an exemplary embodiment, the contacting the point-contacted first and second substrates includes gradually moving upward the plurality of lift pins from the one spot of the first substrate to a circumference of the first substrate.

In an exemplary embodiment, the providing a first substrate includes forming a first protecting layer on the display element and curing the first protecting layer completely or partially.

In an exemplary embodiment, the method further includes forming a passivation layer on the first protecting layer between the forming a first protecting layer and the curing the first protecting layer.

In an exemplary embodiment, the providing a second substrate includes forming a second protecting layer on the second substrate.

In an exemplary embodiment, the method further includes curing the second protecting layer disposed between the first substrate and the second substrate to form a protecting member between the first substrate and the second substrate.

In an exemplary embodiment, the providing a second substrate includes forming a second protecting layer on the second substrate and curing the second protecting layer completely or partially.

In an exemplary embodiment, the providing a first substrate includes forming a first protecting layer on the first substrate.

In an exemplary embodiment, the method further includes curing the first protecting layer disposed between the first substrate and the second substrate to form a protecting member between the first substrate and the second substrate.

An exemplary embodiment provides a method for manufacturing a display device. The method includes forming a display element and a first protecting layer on a first substrate, forming a second protecting layer on a second substrate; disposing the first substrate and the second substrate to face each other, and protruding a part of at least one of the first substrate and the second substrate toward the other point-contacting the first substrate to the second substrate, gradually contacting the point-contacted first and second substrates toward circumferences of the first and second substrates and curing at least one of the first protecting layer and the second protecting layer.

In an exemplary embodiment of the present invention, the method further includes curing the first protecting layer completely or partially after the first protecting layer is formed.

In an exemplary embodiment of the present invention, at least one of the first protecting layer and the second protecting layer includes an organic material.

In an exemplary embodiment the method further includes forming a passivation layer on the first protecting layer.

In an exemplary embodiment, the passivation layer includes an inorganic material.

In an exemplary embodiment, the first protecting layer and the second protecting layer are cured by heat and/or light.

### BRIEF DESCRIPTION OF THE DRAWINGS

The above and/or other aspects and advantages of the prevent invention will become apparent and more readily appreciated from the following description of the exemplary embodiments, taken in conjunction with the accompany drawings, in which:

FIG. 1 illustrates an exemplary embodiment of an apparatus for manufacturing a display device according to the present invention;

FIG. 2 is a plane view illustrating an exemplary embodiment of a gripper in FIG. 1;

FIGS. 3A to 3C illustrate an exemplary embodiment of a method for manufacturing a display device according to the present invention;

FIGS. 4A to 4C illustrate another exemplary embodiment of a method for manufacturing a display device according to the present invention;

FIGS. 5A to 5E illustrate an exemplary embodiment of an operation of providing a first substrate and a second substrate in FIG. 1;

FIG. 6 illustrates a cross-sectional view of an exemplary embodiment of a display device manufactured by a manufacturing method according to the present invention; and

FIG. 7 illustrates a cross-sectional view of another exemplary embodiment of a display device manufactured by a manufacturing method according to the present invention.

### DETAILED DESCRIPTION OF THE INVENTION

Reference will now be made in detail to the embodiments of the present invention, examples of which are illustrated in the accompanying drawings. The embodiments are described below so as to explain the present invention by referring to the figures. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “lower”, “above”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “beneath” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

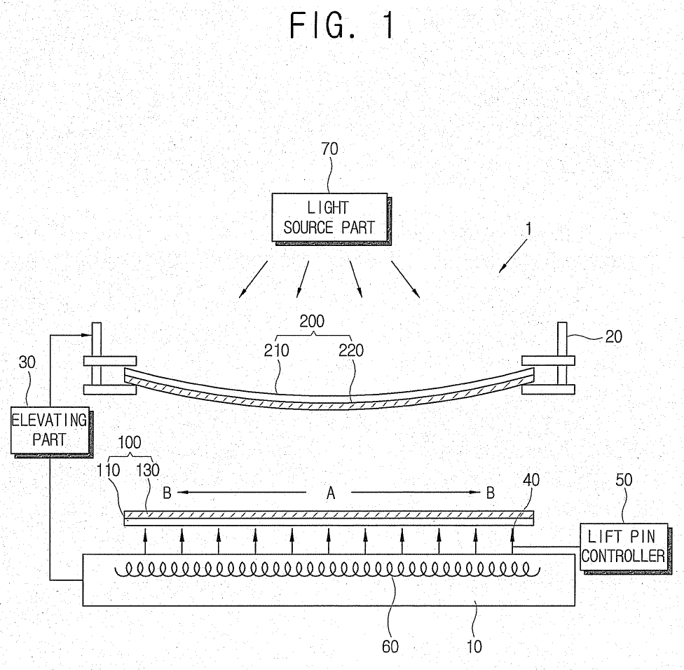

As show in FIG. 1, an exemplary embodiment of a manufacturing method for a display device according to the present invention is performed by a manufacturing apparatus 1. The manufacturing apparatus 1 includes a stage 10 on which a first substrate 100 is mounted, a gripper 20 gripping a second substrate 200, an elevating part 30, a lift pin 40 and a lift pin controller 50. Also, the manufacturing apparatus 1 includes a light source part 70 and a heating member 60, such as a heater, for curing the first substrate 100 and the second substrate 200.

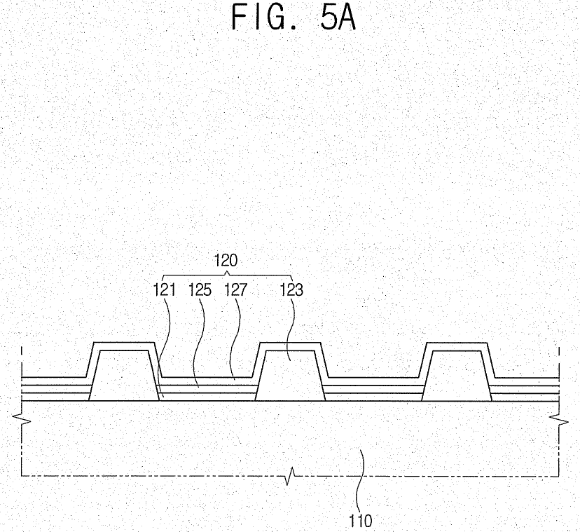

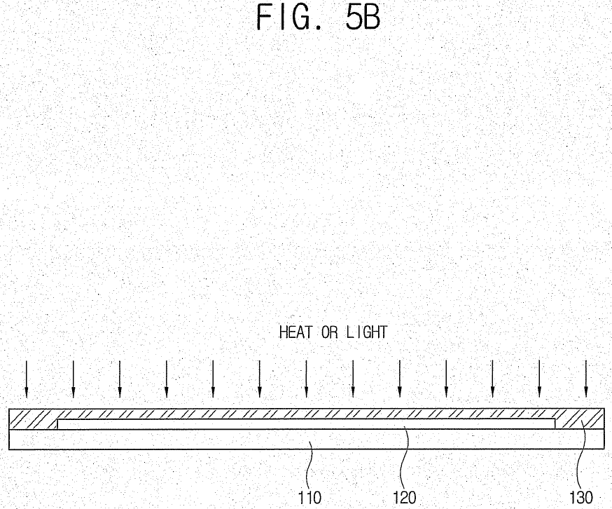

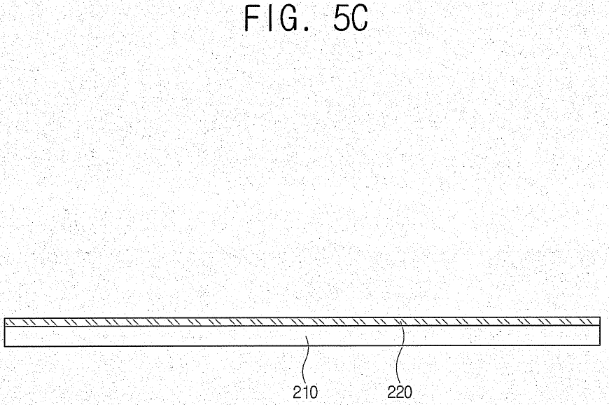

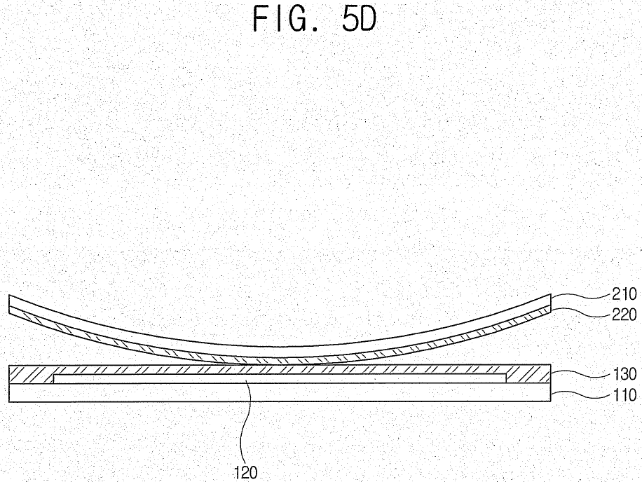

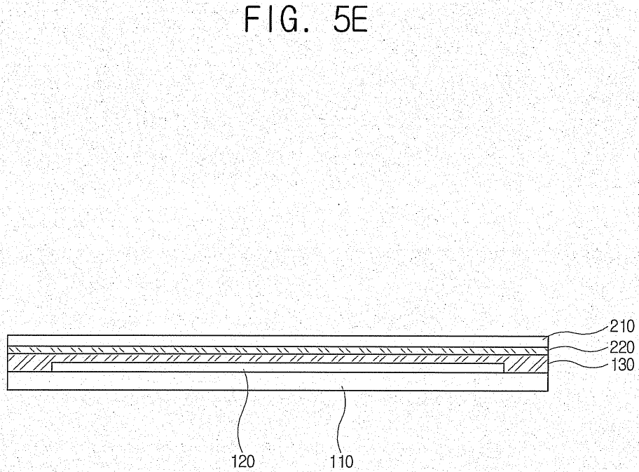

The first substrate 100 and the second substrate 200 have a substantially rectangular shape and are oppositely disposed facing each other. The first substrate 100 includes a first insulation substrate 110 and a first protecting layer 130 formed on (e.g., on a upper surface of) the first insulation substrate 110. A display element (referring to 120 in FIGS. 5A to 5E) is formed between the first protecting layer 130 and the first insulation substrate 110.

The second substrate 200 includes a second insulation substrate 210 and a second protecting layer 220 formed beneath (e.g., at a lower surface of) the second insulation substrate 210. The display device in the illustrated embodiment includes an OLED (organic light emitting diode) including a light emitting layer.

The second substrate 200 is attached to the first substrate 100 to protect the display element formed on the first substrate 100. The first protecting layer 130 and the second protecting layer 220 attach the substrates 100 and 200 to each other to protect the display element from the outside, such as, water and oxygen.

The stage 10 has a substantially rectangular shape and includes the lift pin 40 supporting and vertically moving the first substrate 100.

The lift pin 40 is disposed across substantially an entire surface (e.g., upper surface) of the stage 10. The lift pin 40 isolates or separates the first substrate 100 from the stage 10 by a predetermined distance.

The lift pin controller 50 controls vertical movement of the lift pin 40. The lift pin controller 50 controls the lift pin 40 such that the first substrate 100 is distanced from the stage 10 wholly or partially.

The gripper 20 supports the second substrate 200 to be positioned above the first substrate 100 and grips point parts of the second substrate 200. As in the illustrated embodiment, the gripper 20 holds at least three point parts of the second substrate 200. The gripper 20 releases the second substrate 200 such that the second substrate 200 contacts or drops onto the first substrate 100 to ultimately be attached thereto. In exemplary embodiments, the gripper 20 may be provided as a clamp or the like.

In an exemplary embodiment, when the gripper 20 grips opposite sides of the second substrate 200 and contacts the second substrate 200 to the first substrate 100, an initial contact part of both substrates 100 and 200 may have an oval shape or a rectilinear shape.

If the initial contact part is an oval shape or a rectilinear shape, when the substrates 100 and 200 are finally attached each other, voids may be generated from air between the substrates 100 and 200. The generated voids are difficult to repair and may deteriorate the quality of images when the voids are positioned in the display element. When the gripper 20 grips only the opposite sides of the second substrate 200 and then releases the second substrate 200, it is difficult to control dropping of the second substrate 200 making it difficult to reduce or effectively prevent voids from being generated between the substrates 100 and 200.

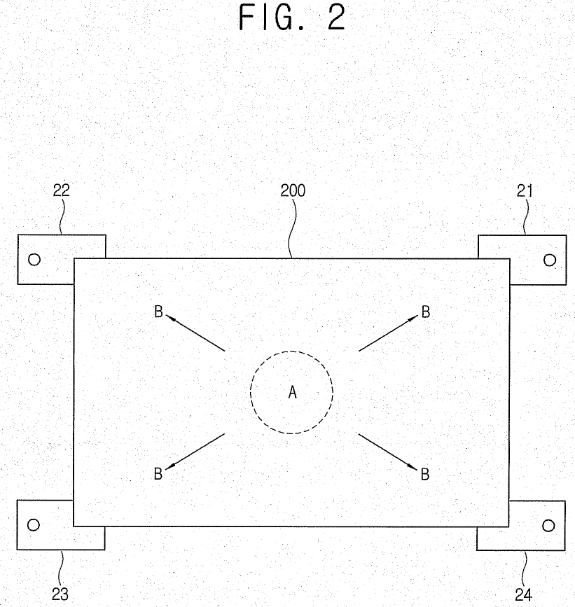

As shown in FIG. 2, the manufacturing apparatus 1 includes a plurality of grippers. First gripper 21, second gripper 22, third gripper 23 and fourth gripper 24 grip four corners of the second substrate 200 as illustrated. A central part A (indicated by the broken circle) of the second substrate 200 sags by self-weight. Alternatively, an force may be applied to the second substrate 200 such that the central part A protrudes toward the first substrate 100 before attaching the first and second substrates 100 and 200.

The second substrate 200 is point-contacted with the first substrate 100. An initial contact part of the both substrates 100 and 200 has a substantially point shape, but may have a circular shape. The initial contact part has a minimum area such that contacting of the remaining part of the first and second substrates 100 and 200 is more controlled than when the initial contact part is an oval shape or a rectilinear shape discussed above.

As in the illustrated embodiment, the initial contact part is the central part A of the substrates 100 and 200. In alternative embodiments, the initial contact part may be point parts or other parts as long as the gripper 20 makes a part of the second substrate 200 protrude toward the first substrate 100 and the initial contact part includes a relatively minimum area.

The substrates 100 and 200 are gradually contacted in a direction moving from the central part A to a circumference B of the first substrate 100. The grippers 21, 22, 23 and 24 slowly release the second substrate 200 onto the first substrate 100. Alternatively, the grippers 21, 22, 23 and 24 may release the second substrate 200 substantially simultaneously or, sequentially to reduce or effectively prevent voids from being generated. Releasing of the grippers 21, 22, 23 and 24 is controlled to minimize voids between the substrates 100 and 200 during attachment.

In an alternative embodiment, the gripper 20 may grip sides (e.g., peripheral points) of the second substrate 200. The gripper 20 may grip at least three parts of the second substrate 200 to stably support the second substrate, but the invention is not limited thereto.

Referring again to FIG. 1, the elevating part 30 vertically moves the griper 20 with respect to the stage 10 to control a distance between the substrates 100 and 200 such that the substrates 100 and 200 can be contacted and/or moved away from each other. The elevating part 30 may move both of the stage 10 and the gripper 20 at essentially the same time, or may move one of the stage and the gripper while the other one remains fixed.

The heater 60, which may be provided in the stage 10, heats the first protecting layer 130 of the first substrate 100, or the first protecting layer 130 and the second protecting layer 220 between the substrates 100 and 200 after the substrates 100 and 200 contact each other. In an exemplary embodiments, the first protecting layer 130 and/or the second protecting layer 220 may be made of thermosetting resin.

The light source part 70, which may be provided above the second substrate 200 and essentially functions the same as the heater 60. The light source part 170 applies light to the second protecting layer 220 of the second substrate 200, or to the first protecting layer 130 and the second protecting layer 220 of the substrates 100 and 200, after the substrates 100 and 200 contact each other to cure the protecting layers 130 and 220. In an exemplary embodiment, the light source part 70 may include a lamp emitting light or an ultraviolet ray.

In exemplary embodiments, the manufacturing apparatus 1 may include at least one of the heater 60 and the light source part 70.

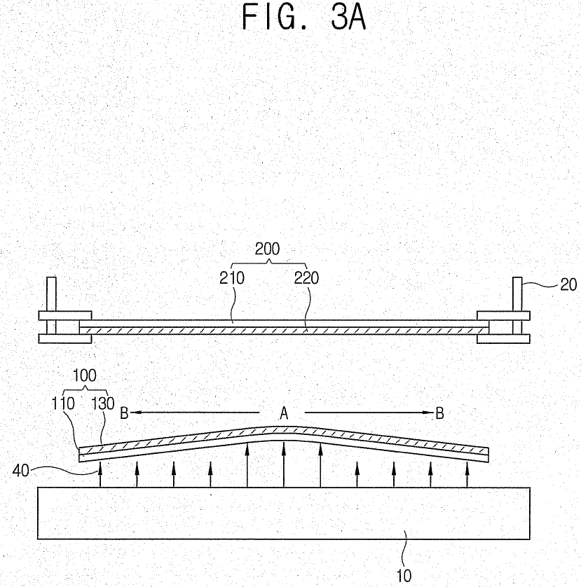

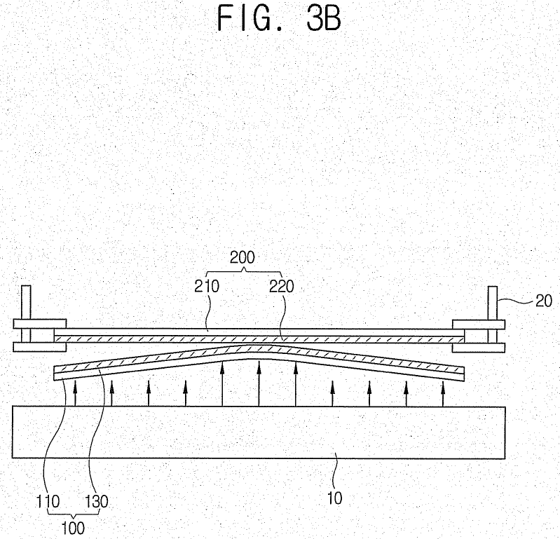

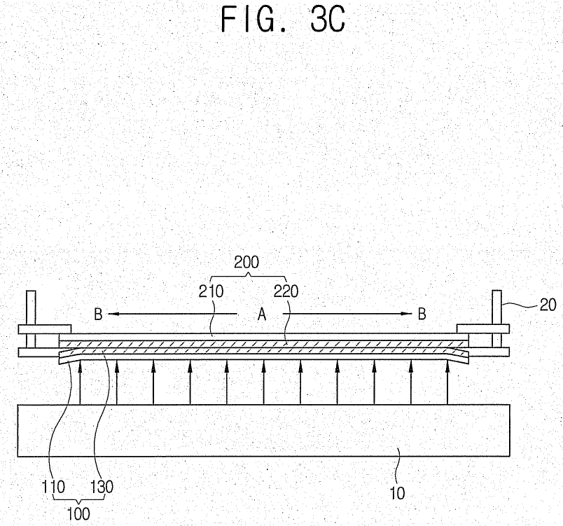

Hereinafter, an exemplary embodiment of a method for manufacturing a display device according to the present invention will be described by referring to FIGS. 3A to 3C.

As shown in FIGS. 3A to 3C, a central part A of a first substrate 100 protrudes toward a second substrate 200, unlike FIG. 1.

Referring to FIG. 3A, a plurality of lift pins 40 are upward/downward movably provided on the stage 10. Some lift pins 40 corresponding to the central part A of the first substrate 100 are moved upward to lift the central part A to be higher than other parts of the first substrate 100. The gripper 20 grips the second substrate 200 to be substantially flat.

Referring to FIG. 3B, a distance between the substrates 100 and 200 is controlled so that the substrates 100 and 200 are point-contacted.

Referring to FIG. 3C, the substrates 100 and 200 are gradually contacted from the central part A towards a circumference B of the first substrate 100. The lift pin controller 50 controls the lift pins 40 to gradually lift up the first substrate 100 toward the second substrate 200 from the central part A to the circumference B.

The central part A of the first substrate 100 mounted on the stage 10 protrudes by means of the lift pins 40 to contact the second substrate 200. Then, the lift pins 40 are gradually moved upward (from central lift pins 40 to outer lift pins 40) to contact the first substrate 100 to the second substrate 200.

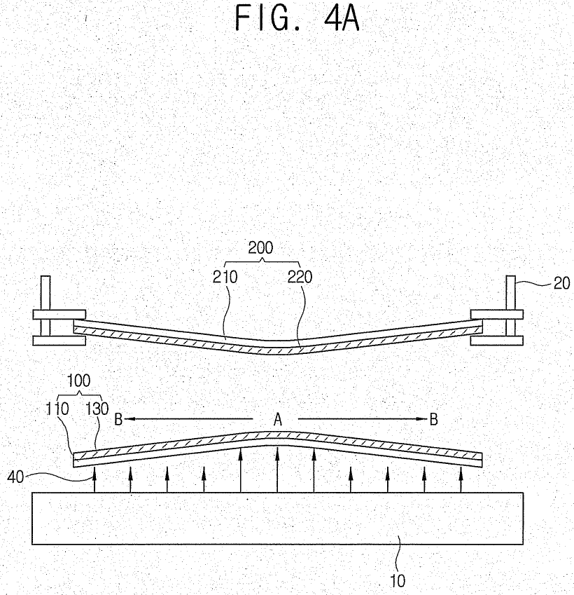

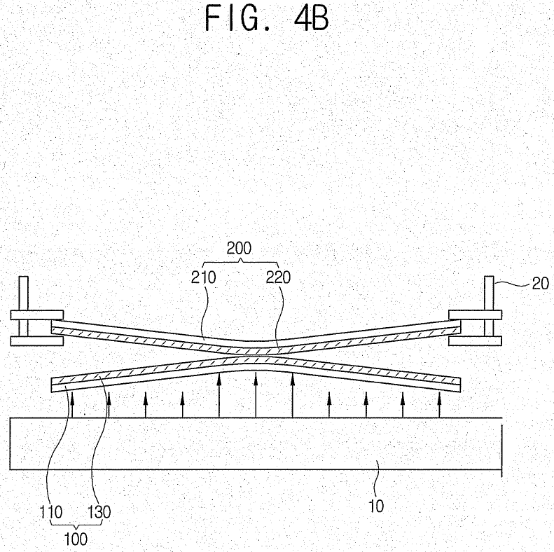

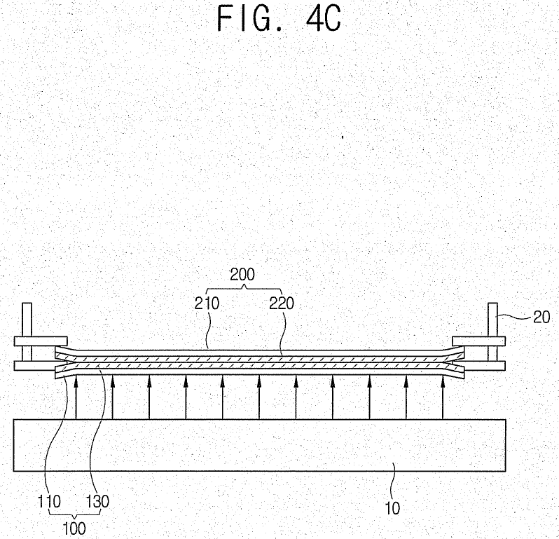

Hereinafter, another exemplary embodiment of a method for manufacturing a display device according to the present invention will be described by referring to FIGS. 4A to 4C.

Referring to FIG. 4A, respective central parts of a first substrate 100 and a second substrate 200 protrude toward each other. The first substrate 100 protrudes upward by means of the lift pins 40 and the second substrate 100 protrudes downward by means of the gripper 20.

Referring to FIG. 4B, the elevating part 30 moves the stage 10 and/or the gripper 20 relative to each other such that the central parts A of the substrates 100 and 200 are point-contacted.

Referring to FIG. 4C, the gripper 20 gradually releases or moves the second substrate 200 and the lift pins 40 gradually lifts up the first substrate 100 so that the substrates 100 and 200 are contacted from the central parts A to circumferences B of the substrates 100 and 200.

As in the illustrated embodiments, the manufacturing methods according to the present invention can be applied to manufacturing of a liquid crystal display device so that a thin film transistor substrate and a color filter substrate are attached each other, or to manufacturing of other devices which require attaching multiple substrates.

Hereinafter, an exemplary embodiment of an operation of providing the first substrate and the second substrate according to the present invention will be described in detail by referring to FIGS. 1, 2 and 5A to 5E.

Referring to FIG. 5A, a display element 120 is formed on the first insulation substrate 110. The display element 120 includes a first electrode 121, a second electrode 127 facing the first electrode 121 and a light emitting layer 125 disposed between the first electrode 121 and the second electrode 127. Electrical and chemical properties of the display element 120 may be deteriorated by external elements, such as water and/or oxygen, thereby deteriorating the durability of the display element 120.

The first electrode 121 is disposed on (e.g., an upper surface) the first insulation substrate 110 and the second electrode 127 is oppositely disposed to face the first electrode 121. In exemplary embodiments, the first electrode 121 may include, but is not limited to, a transparent conductive material such as ITO (indium tin oxide), IZO (indium zinc oxide), etc. The second electrode 127 may include, but is not limited to calcium, barium, magnesium, silver, copper, aluminum, or an alloy thereof.

A wall 123 is formed between adjacent first electrodes 121 (e.g., in a direction substantially parallel to the first insulation substrate 110) to electrically isolate the adjacent first electrodes 121.

In exemplary embodiments, the light emitting layer 125 may include, but is not limited to, organic materials for emitting red, green and/or blue light. The light emitting layer 125 may be formed by any of a number of methods, such as including a depositing method, an inkjet printing method, etc.

When electrons supplied through the second electrode 127 and holes supplied through the first electrode 121 are combined in the light emitting layer 125, excitons are generated in the light emitting layer 125. The excitons radiate light toward the first substrate 100 while transitioning from an excited state to a ground state.

In an exemplary embodiment, the display element 120 may further include at least one of a hole injection layer (not shown), a hole transporting layer (not shown), an electron injection layer (not shown) and an electron transporting layer (not shown) between the first electrode 121 and the second electrode 127, in addition to the light emitting layer 125.

In alternative exemplary embodiments, the first electrode 121 may include metal such as calcium, barium, magnesium, silver, copper, aluminum, or an alloy thereof, and the second electrode 127 may include a transparent conductive material such that light radiates toward the second substrate 200.

Referring to FIG. 5B, the first protecting layer 130 is formed over the display element 120.

In exemplary embodiments, the first protecting layer 130 may include an organic material or an inorganic material, or may be provided as a compound layer including an organic material and an inorganic material. A part of the first protecting layer 130 which contacts the display element 120 may include an organic material. In one exemplary embodiment, the first protecting layer 130 may include an organic material such as polyacetylene, polyimide, epoxy resin or the like, or an inorganic material such as silicon oxide, silicon nitride, magnesium oxide, aluminum oxide, aluminum nitride, titanium oxide or the like.

In an exemplary embodiment, the first protecting layer 130 may be formed over the display element 120 by any of a number of methods, such as including a screen printing method, a roll printing method, a slit coating method, a dropping method, etc. The dropping method can be relatively simply and rapidly used to form the first protecting layer 130. Alternatively, the organic material may be deposited and the inorganic material may be sputtered to form the first protecting layer 130.

In exemplary embodiments, the first protecting layer 130 may include one of thermosetting resin and light curable resin such as UV curable resin. Alternatively, the first protecting layer 130 may include material which is curable to both heat and light. The material is formed on the first insulation substrate 110, and then is cured by heat and/or light (as shown by the arrows in FIG. 5B) to form the first protecting layer 130.

In the illustrated embodiment, the first protecting layer 130 may be completely or partially cured. Since the first protecting layer 130 is cured before the first substrate 100 and the second substrate 200 are attached each other, gases generated during the curing process may radiate into the air. Accordingly, deterioration of the display element 120 can be reduced or effectively prevented due to the generated gases.

Referring to FIG. 5C, the second protecting layer 220 is formed on the second insulation substrate 210.

The second protecting layer 220 reduces or effectively prevents the display element 120 from directly contacting with water or oxygen which may damage the display element 120. The second insulation substrate 210 may include the same material as the first insulation substrate 110, or glass.

The second insulation substrate 210 may have a thickness such as to prevent deterioration element, such as water or oxygen, from infiltrating into the display element 120 through the second substrate 200. A chemical reaction of the display element 120 with water or oxygen can be reduced or effectively prevented by the thickness of the second insulation substrate 210. In determining the thickness of the second insulation substrate 210, impact resistance of the second substrate 210 and overall weight of the display device may be considered.

In exemplary embodiments, the second protecting layer 220 may include an organic material or an inorganic material, or may be provided as a compound layer including an organic material and an inorganic material. The second protecting layer 220 may include an organic material such as polyacetylene, polyimide, epoxy resin or the like, or an inorganic material such as silicon oxide, silicon nitride, magnesium oxide, aluminum oxide, aluminum nitride, titanium oxide or the like.

The second protecting layer 220 may be formed by any of a number of methods, such as including a screen printing method, a roll printing method, a slit coating method, a dropping method, etc. The dropping method can relatively simply and rapidly form the second protecting layer 220. Alternatively, the organic material may be deposited and the inorganic material may be sputtered.

In exemplary embodiments, the second protecting layer 220 may include one of thermosetting resin and light curable resin such as UV curable resin.

Referring to FIGS. 1 and 5D, the central part A of the second substrate 200 protrudes toward the first substrate 100.

Alternatively, referring to FIGS. 3A to 4C, the central part A of the first substrate 100 may protrude toward the second substrate 200, or the central parts A of both substrates 100 and 200 may protrude towards each other.

Referring to FIG. 5E, the second protecting layer 220 which is not cured and disposed between the substrates 100 and 200 is cured by heat and/or light. The substrates 100 and 200 are stably attached each other without any voids, and can be provided with protecting members protecting the display element 120 from deterioration elements, such as water, oxygen or the like.

As in the illustrated embodiments, the protecting members 130 and 220 formed with the first protecting layer 130 and the second protecting layer 220 enhance durability and display properties of the display element 120, and reduces or effectively prevents bending of the substrates 100 and 200. Also, the protecting members 130 and 220 suppress bubbles, which may significantly deteriorate the quality of images produced by the display element 120, from being generated between the substrates 100 and 200.

In exemplary embodiments, the first protecting layer 130 and the second protecting layer 220 may be provided with a moisture absorbing layer (not shown). The moisture absorbing layer may be formed between the first protecting layer 130 and the second protecting layer 220. When the display device further include a passivation layer, the moisture absorbing layer may be formed between the passivation layer and the second protecting layer 220. The moisture absorbing layer may include moisture absorbent such as calcium, barium, calcium oxide, barium oxide or the like, which is apt to react to water and/or oxygen.

In an alternative embodiment, the second protecting layer 220 may be completely or partially cured instead of the first protecting layer 130. After the substrates 100 and 200 are contacted each other, the first protecting layer 130 can be completely cured to form the protecting members between the substrates 100 and 200.

In an alternative embodiment, after both protecting layers 130 and 220 are partially cured and the substrates 100 and 200 are contacted each other, both protecting layers 130 and 220 can then be completely cured.

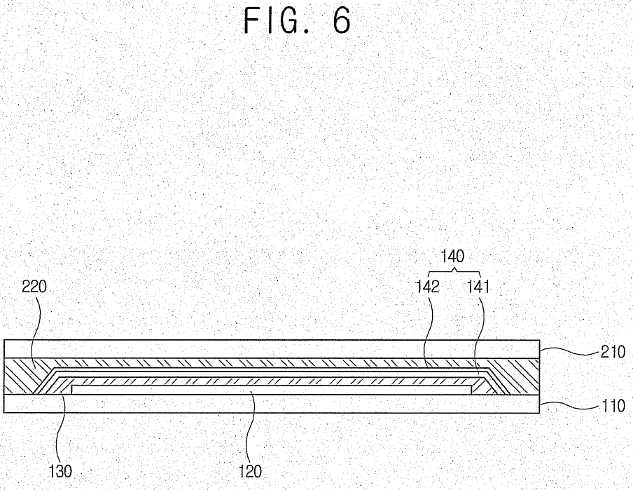

Hereinafter, an exemplary embodiment of a display device manufactured by a manufacturing method according to the present invention will be described by referring to FIG. 6.

As shown in FIG. 6, a display device includes a passivation layer 140 formed over a first protecting layer 130. The passivation layer 140 covers the first protecting layer 130 to reduce or effectively prevent a display element 120 from contacting water and oxygen. If the first protecting layer 130 is made of an organic material, the passivation layer 140 efficiently protects the first protecting layer 130.

In exemplary embodiments, the passivation layer 140 may be provided as an organic layer, an inorganic layer or a compound layer including an organic material and an inorganic material. The passivation layer 140 may further include a moisture absorbing layer.

In the illustrated embodiment, the passivation layer 140 includes an organic layer 141 contacting the first protecting layer 130, and an inorganic layer 142 contacting a second protecting layer 220. The organic layer 141 contacts the inorganic layer 142.

In an alternative embodiment, the organic layer 141 may contact the second protecting layer 220 and the inorganic layer 142 may contact the first protecting layer 130. Alternatively, at least one organic layer 141 and at least one inorganic layer 142 may be alternately disposed between the protecting layers 130 and 220. The moisture absorbing layer may be provided between the organic layer 141 and the inorganic layer 142.

In the passivation layer 140, the organic layer 141 may include a polyacetylene layer, a polyimide layer or the like, and the inorganic layer may include a SiO layer, a SiN layer, a SiON layer, a MgO layer, an AlO layer, a TiO layer or the like. When the passivation layer 140 includes the inorganic layer 142, the passivation layer 140 may be formed by a sputtering method.

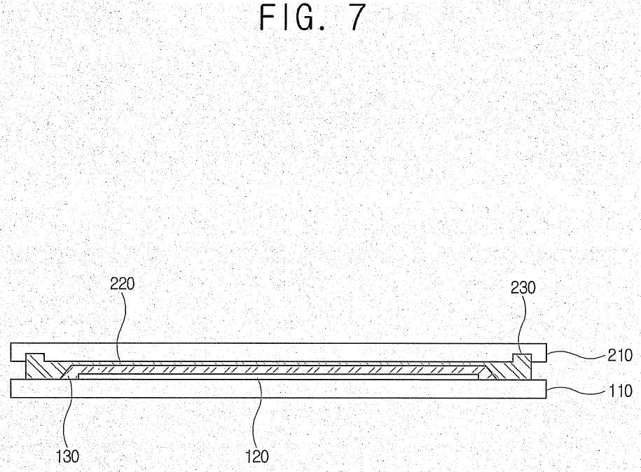

Hereinafter, another exemplary embodiment of a display device manufactured by a manufacturing method according to the present invention will be described by referring to FIG. 7.

As shown in FIG. 7, a display device includes a stain preventing groove 230. The stain preventing groove 230 is formed in a circumference (or peripheral area) of a second substrate 200. The stain preventing groove 230 reduces or effectively prevents staining of a driving circuit part (not shown) formed on a first substrate 100 by protecting layers 130 and 220 flowing out of a gap between the first substrate 100 and the second substrate 200.

Alternatively, the stain preventing groove 230 may be discontinuously formed in a circumference (or peripheral area) of the first substrate 100.

As in the illustrated embodiments, an apparatus and method for manufacturing a display device are capable of reducing or effectively preventing voids from being generated between a first substrate and a second substrate, thereby preventing deterioration of a display element, and thereby enhancing durability of the display element.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. An apparatus for manufacturing a display device, the apparatus comprising:
a stage on which a lower substrate is mounted, the stage comprising a plurality of lift pins formed on an entire surface of the stage;
a gripper that grips at least three point parts of an upper substrate to be positioned above the lower substrate; and
an elevating part that vertically moves at least one of the stage and the gripper relative to the other.

2. The apparatus according to claim 1, wherein the upper substrate comprises a rectangular shape and the gripper grips four corners of the upper substrate.

3. The apparatus according to claim 1, further comprising a lift pin controller that controls the lift pins to gradually ascend from a predetermined part of the stage to a circumference of the stage.

4. The apparatus according to claim 3, wherein the predetermined part comprises a central part.

5. The apparatus according to claim 1, further comprising a light source part that emits light to the lower substrate and the upper substrate.

6. The apparatus according to claim 1, further comprising a heater that heats the lower substrate and the upper substrate.

7. A method for manufacturing a display device, the method comprising:
providing a first substrate on which a display element is formed;
providing a second substrate on the first substrate, the second substrate facing the first substrate;
protruding a part of at least one of the first substrate and the second substrate toward the other;
point-contacting the first substrate to the second substrate; and
gradually contacting the point-contacted first and second substrates toward circumferences of the first and second substrates.

8. The method according to claim 7, wherein the second substrate comprises a rectangular shape, and
wherein the protruding a part of at least one of the first substrate and the second substrate comprises gripping four corners of the second substrate so that one spot of the second substrate protrudes downward.

9. The method according to claim 8, wherein the contacting the point-contacted first and second substrates comprises lowering gradually the second substrate from the one spot to the circumference of the second substrate.

10. The method according to claim 7, wherein the protruding a part of at least one of the first substrate and the second substrate comprises:
mounting the first substrate on a stage comprising a plurality of lift pins vertically movably formed on an entire surface of the stage; and
moving upward a lift pin corresponding to the one spot of the first substrate.

11. The method according to claim 10, wherein the contacting the point-contacted first and second substrates comprises gradually moving upward the plurality of lift pins from the one spot of the first substrate to a circumference of the first substrate.

12. The method according to claim 8, wherein the protruding a part of at least one of the first substrate and the second substrate comprises:
mounting the first substrate on a stage comprising a plurality of lift pins vertically movably formed on an entire surface of the stage; and
moving upward a first lift pin corresponding to one spot of the first substrate.

13. The method according to claim 12, wherein the contacting the point-contacted first and second substrates comprises gradually moving upward the plurality of lift pins from the one spot of the first substrate to a circumference of the first substrate.

14. The method according to claim 7, wherein the providing a first substrate comprises:
forming a first protecting layer on the display element; and
curing the first protecting layer completely or partially.

15. The method according to claim 14, further comprising forming a passivation layer on the first protecting layer between the forming a first protecting layer and the curing the first protecting layer.

16. The method according to claim 14, wherein the providing a second substrate comprises forming a second protecting layer on the second substrate.

17. The method according to claim 16, further comprising curing the second protecting layer disposed between the first substrate and the second substrate to form a protecting member between the first substrate and the second substrate.

18. The method according to claim 15, wherein the providing a second substrate comprises forming a second protecting layer on the second substrate.

19. The method according to claim 18, further comprising curing the second protecting layer disposed between the first substrate and the second substrate to form a protecting member between the first substrate and the second substrate.

20. The method according to claim 7, wherein the providing a second substrate comprises:
forming a second protecting layer on the second substrate; and
curing the second protecting layer completely or partially.

21. The method according to claim 7, wherein the providing a first substrate comprises forming a first protecting layer on the first substrate.

22. The method according to claim 21, further comprising curing the first protecting layer disposed between the first substrate and the second substrate to form a protecting member between the first substrate and the second substrate.

23. A method for manufacturing a display device, comprising:
forming a display element and a first protecting layer on a first substrate;
forming a second protecting layer on a second substrate;
disposing the first substrate and the second substrate to face each other, and protruding a part of at least one of the first substrate and the second substrate toward the other;
point-contacting the first substrate to the second substrate;
gradually contacting the point-contacted first and second substrates toward circumferences of the first and second substrates; and
curing at least one of the first protecting layer and the second protecting layer.

24. The method according to claim 23, further comprising curing the first protecting layer completely or partially after the first protecting layer is formed.

25. The method according to claim 23, wherein at least one of the first protecting layer and the second protecting layer comprises an organic material.

26. The method according to claim 23, further comprising forming a passivation layer on the first protecting layer.

27. The method according to claim 26, wherein the passivation layer comprises an inorganic material.

28. The method according to claim 23, wherein the first protecting layer and the second protecting layer are cured by heat and/or light.
